(19) United States
(12) Patent Application Publication
(10) Pub. No.: US 2009/0072369 A1
(43) Pub. Date: Mar. 19, 2009

(54) SEMICONDUCTOR DEVICE

(75) Inventor: Makoto OIKAWA, Gunma (JP)

Correspondence Address: MORRISON & FOERSTER LLP, 1650 TYSONS BOULEVARD, SUITE 400, MCLEAN, VA, 22102, US

(73) Assignees: SANYO Electric Co., Ltd., Moriguchi-shi (JP); SANYO Semiconductor Co., Ltd.

(21) Appl. No.: 12/199,611

(22) Filed: Aug. 27, 2008

(30) Foreign Application Priority Data
Sep. 13, 2007 (JP) 2007-238289

(51) Int. Cl. H01L 23/495

(52) U.S. Cl. 257/676; 257/E23.031

(57) ABSTRACT

Provided is a semiconductor device. In the semiconductor device, a rectangular header with two mounting regions is folded, and two semiconductor chips are then fixed respectively to the mounting regions facing each other. Thereby, a stacked structure of the semiconductor chips is achieved while a mounting area of a package remains the same as the area for one semiconductor chip of a conventional type. Furthermore, characteristics of the two semiconductor chips can be obtained. Accordingly, compared with a case in which one semiconductor chip is used, on-resistance is decreased due to an increase in the number of transistor cells. Thereby, the semiconductor device can be driven at a low voltage. In addition, a larger current capacity can be achieved. Moreover, compared with a case in which two semiconductor chips are mounted next to each other on the header, a mounting area of a package outline can be reduced.

This application claims priority from Japanese Patent Application Number JP 2007-238289 filed on Sep. 13, 2007, the content of which is incorporated herein by reference in its entirety.

### BACKGROUND OF THE INVENTION

1. Field of the Invention

The present invention relates to a semiconductor device and, particularly, to a semiconductor device having a high breakdown voltage and a large current capacity, and reduced in size.

2. Description of the Related Art

As so-called power discrete semiconductor (single-function semiconductor) elements having a high breakdown voltage and a large current capacity, insulated gate bipolar transistors (IGBT), metal oxide semiconductor field effect transistors (MOSFET), and diodes are known, for example.

FIG. 4 shows one example of a conventional semiconductor device. FIG. 4 is a plan view showing a case where an IGBT semiconductor chip is mounted on a frame.

A number of IGBT cells are provided in a portion of a semiconductor chip 210, the portion being on a main surface side of the semiconductor chip 210. In addition, an emitter electrode 212, which covers surfaces of the cells and are connected to the cells, and a gate pad electrode 211 are provided in a portion of the semiconductor chip 210, the portion being on the main surface side of the semiconductor chip 210. A metal is vapor-deposited on an entire back surface (unillustrated) of the semiconductor chip, and a collector electrode is provided thereon.

A frame 213 is a stamped frame made of copper. The back surface (collector electrode) of the semiconductor chip 210 is fixed to a header portion of the frame with a preform material, and a lead portion continued to the header portion is led to the outside of the frame, as a collector terminal 216.

Meanwhile, the emitter electrode 212 and the gate pad electrode 211 on the surface of the semiconductor chip 210 are connected, with wires 217, to another frame 213 (lead portion) which is separated from the header portion. Thereby, the emitter electrode 212 and the gate pad electrode 211 are led to the outside of the frame, as a gate terminal 214 and an emitter terminal 215.

The semiconductor chip 210 and the frame 213 are integratedly covered with a resin layer 218 forming a package. This technology is described for instance in Japanese Patent Application Publication No. 2004-103995.

Power semiconductor devices are used for controlling flashes (strobe) of digital still cameras (DSC) and cameras integrated in mobile phones, for example. Along with reduction in size of the DSC and mobile phones, a market demand for small semiconductors and semiconductors using smaller driving voltage, has been increasing. However, as the semiconductor devices become smaller, lead pins of terminals are arranged more closely. In such a case, a breakdown voltage are likely to be deteriorated in some arrangements of the terminals (lead pins). For this reason, in order to form a semiconductor device with a higher breakdown voltage and a larger current capacity, it is necessary to increase the number of IGBT cells and to use a substrate (chip) large in size, in general. In other words, semiconductor devices can hardly be downsized while maintaining at least current characteristics thereof.

### SUMMARY OF THE INVENTION

The invention provides a semiconductor device that includes a first frame having a header portion and a first lead portion extending from the header portion. The header portion includes a first mounting region and a second mounting region and is bent over so that the first mounting region faces the second mounting region. The device also include a first discrete semiconductor chip having a bottom surface attached to the first mounting region and a top surface on which a first bump electrode is formed, and a second discrete semiconductor chip having a bottom surface attached to the second mounting region and a top surface on which a second bump electrode is formed. The device further includes a second frame disposed between the first and second mounting regions and connected to the first and second discrete semiconductor chips. The second frame also has a second lead portion.

### BRIEF DESCRIPTION OF THE DRAWINGS

FIGS. 1A and 1B are plan views for illustrating a semiconductor device according to the present invention. FIG. 1C is a cross-sectional view for illustrating the semiconductor device according to the present invention;

FIG. 2 is a schematic cross-sectional view for illustrating the semiconductor device according to the present invention;

FIG. 3A to 3E are equivalent circuit diagrams for illustrating the semiconductor device according to the present invention; and

FIG. 4 is a plan view for illustrating a conventional semiconductor device.

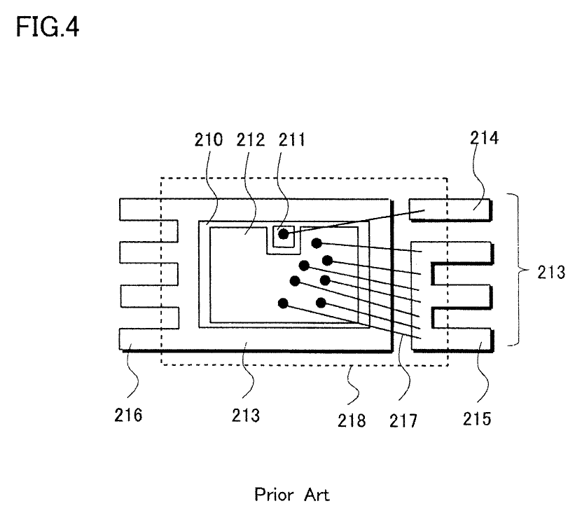

### DESCRIPTION OF THE INVENTION

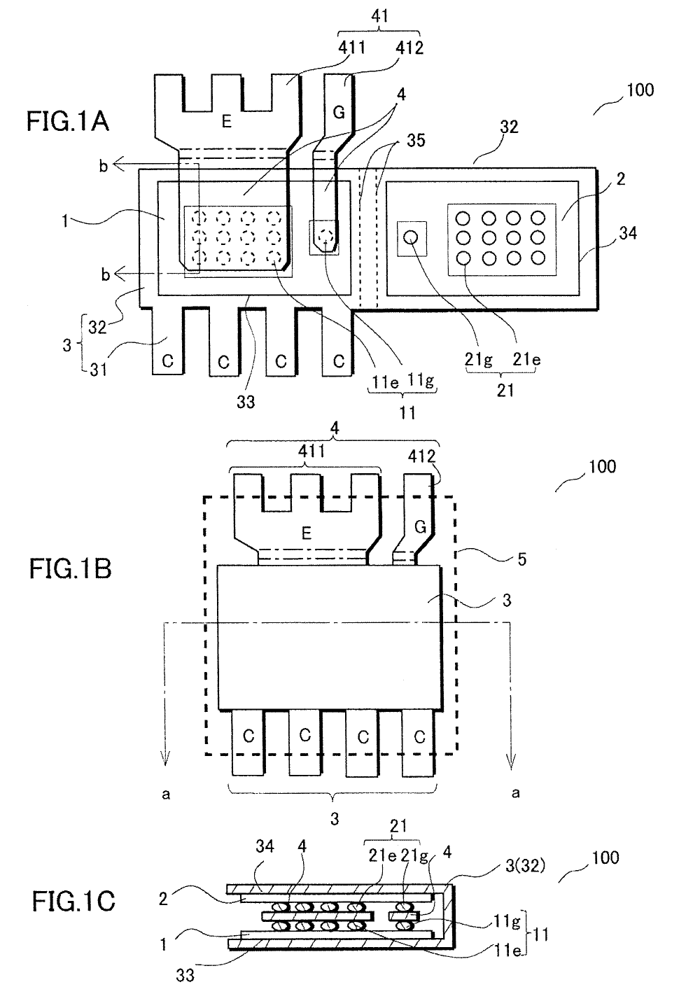

Preferred embodiments of the present invention will be described in details by referring to FIGS. 1A, 1B, 1C, 2, 3A, 3B, 3C, 3D, and 3E.

A semiconductor device according to the present embodiment is formed of first and second semiconductor chips and first and second frames.

FIGS. 1A to 1C are views showing a semiconductor device 100. Specifically, FIG. 1A is an exploded plan view of the semiconductor device 100. FIG. 1B is a plan view after the semiconductor device 100 is assembled. FIG. 1C is a cross-sectional view taken along the a-a line in FIG. 1B.

As shown in FIG. 1A, a first frame 3 is a stamped frame formed of, for example, copper or the like and has a lead portion 31 and a header portion 32. The header portion 32 is a rectangular shape having first side S1 and second side S2 and has first and second mounting regions 33 and 34, which are arranged in line along the second side S2. In addition, the lead portion 31 of the first frame 3 leads out in an extending direction of the first side S1 of the header portion 32.

A first semiconductor chip 1 is fixed to and mounted on the first mounting region 33. The first semiconductor chip 1 is a discrete semiconductor chip and is a semiconductor chip on which, for example, a number of IGBT transistor cells are provided. In addition, first bump electrode 11 (shown by circles of broken lines) is provided on one main surface of the first semiconductor chip 1. The first bump electrode 11 includes emitter bump electrodes 11e and a gate bump electrode 11g, which are respectively connected to emitter electrodes and a gate pad electrode of IGBT. In addition, a collector electrode is provided on the unillustrated back surface of the first semiconductor chip 1.

A second semiconductor chip 2 is fixed to and mounted on the second mounting region 34. The second semiconductor chip 2 is also a discrete semiconductor chip. Here, as one example, the second semiconductor chip is an IGBT semiconductor chip with the same pattern and same size as those of the first semiconductor chip 1. Second bump electrode 21 is provided on one main surface of the second semiconductor chip 2. The second bump electrode 21 includes emitter bump electrodes 21e and a gate bump electrode 21g, which are respectively connected to emitter electrodes and a gate pad electrode of IGBT. In addition, a collector electrode is provided on the unillustrated back surface of the second semiconductor chip 2.

The lead portion 31 of the first frame 3 leads out to an outside of the frame as a collector terminal C of the first and second semiconductor chips 1 and 2.

The second frame 4 is a stamped frame formed of, for example, copper and is connected to the bump electrodes of the first and second semiconductor chips 1 and 2. In the present embodiment, FIG. 1A shows a state where the second frame 4 is fixed to the first bump electrode 11 of the first semiconductor chip 1. However, the second frame 4 is also fixed to the second bump electrode 21 of the second semiconductor chip 2 (to be described later).

The second frame 4 has lead portion 41 leading out in an extending direction of the first side S1 of the header portion 32 of the first frame 3. The lead portion 41 includes a first lead portion 411 leading out in an outside of the frame as an emitter terminal E of the first semiconductor chip 1 and a second lead portion 412 leading out in an outside of the frame as a gate terminal G of the first semiconductor chip 1.

As shown in FIGS. 1A and 1B, the header portion 32 of the first frame 3 is folded back in the extending direction of the second side S2 by folding lines 35 parallel to the first side S1, the folding lines positioned between the first and second mounting regions 33 and 34.

In addition, the first and second semiconductor chips 1 and 2 and the first and second frames 3 and 4 are integratedly covered with and supported by a resin layer 5 shown by the thick broken line. Thereby, a semiconductor device with three terminals is formed.

As shown in FIG. 1C, the first and second semiconductor chips 1 and 2 which are fixed to the first and second mounting regions 33 and 34, are arranged so as to face to each other because the header portion 32 of the first frame 3 is folded. In addition, the second frame 4 is arranged between the first and second semiconductor chips 1 and 2.

In the present embodiment, the first and second lead portions 411 and 412 are commonly used by the first and second semiconductor chips 1 and 2. Thereby, the first and second semiconductor chips 1 and 2 are arranged to be line-symmetric in relation to the folding lines 35 (see, FIG. 1A).

Thereby, the second frame 4 has the one main surface being fixed to the first bump electrode 11 of the first semiconductor chip 1 and the other main surface being fixed to the second bump electrode 21 of the second semiconductor chip 2.

The first lead portion 411 of the second frame 4 is also connected to the emitter electrodes of the second semiconductor chip 2, commonly with the first semiconductor chip 1. The second lead portion 412 is also connected to the gate electrode of the second semiconductor chip 2, commonly with the first semiconductor chip 1 (see, FIG. 1B).

As described above, the semiconductor device of the present embodiment has a structure in which the first and second semiconductor chips 1 and 2 are respectively fixed to the first and second mounting regions 33 and 34 of the header portion 32, which is folded along the folding lines 35 to bring the first and second mounting regions 33 and 34 to face to each other. In the structure, the first and second bump electrodes 11 and 21 are respectively connected to the main surfaces of the second frame 4 arranged therebetween.

The collector electrodes of the first and second semiconductor chips 1 and 2 are commonly connected to the lead portion 31 of the first frame 3 and are led to the outside of the frame as collector terminals C.

In addition, the emitter bump electrodes 11e and 21e of the first and second semiconductor chips 1 and 2 are commonly connected to the first lead 411 of the second frame 4 and are led to the outside of the frame as emitter terminals E. Similarly, the gate bump electrodes 11g and 21g of the first and second semiconductor chips 1 and 2 are commonly connected to the second lead 412 of the second frame 4 and are led to the outside of the frame as a gate terminal G.

The first and second semiconductor chips 1 and 2 are IGBT with the same chip size and the same pattern. Thereby, two semiconductor chips can be mounted on a mounting area for one semiconductor chip. In other words, if the chip sizes of the first and second semiconductor chips 1 and 2 are equal to a size of a conventional one, a less driving voltage due to a less on-resistance or a larger current capacity is achieved without increasing the mounting area, when compared with the case where one semiconductor chip is mounted. When compared with the case where two semiconductor chips are mounted on the same plane (or a case where a semiconductor chip whose chip size is double is mounted), the semiconductor device can be downsized while maintaining characteristics thereof.

In addition, the semiconductor device has a structure in which the surfaces of the first and second semiconductor chips 1 and 2 (for example, a set of the emitter bump electrodes 11e and the gate bump electrode 11g and a set of the emitter bump electrodes 21e and the gate bump electrode 21g) are caused to face to each other. Thereby, complicated manufacturing processes can be avoided. The electrode patterns of an emitter electrode 118 and a gate pad electrode (unillustrated, or a gate wiring 119) need to be separated. For this reason, in the structure in which the back surfaces (the collector electrodes 120) of the chip are caused to face to each other (that is, the structure in which the emitter electrode 118 and the gate pad electrode (gate wiring 119) are arranged on the outside), the manufacturing processes become complicated. In the present embodiment, a stacked structure of two semiconductor chips can be easily achieved.

Furthermore, the semiconductor device has a structure in which one frame (the first frame) mounting the first and second semiconductor chips 1 and 2 is folded. Thereby, the semiconductor device has a uniform heat releasing property when compared with the structure in which, for example, multiple metal plates are bonded to form a single frame. Thus, the structure contributes to a decrease of a resistance value.

Moreover, in the present embodiment, the lead portion 31 (lead pin) of the first frame 3 to be the high potential collector terminals C and the lead portion 411 (lead pin) of the second frame 4 to be the low (GND) potential emitter terminal E face to each other sandwiching the resin layer 5. Thereby, enough distance is provided between the high potential lead pins and the low potential lead pin. Accordingly, a higher breakdown voltage can be achieved when compared with the structure in which, for example, a high potential lead pin and a low potential lead pin are led to the same side of the package (resin layer).

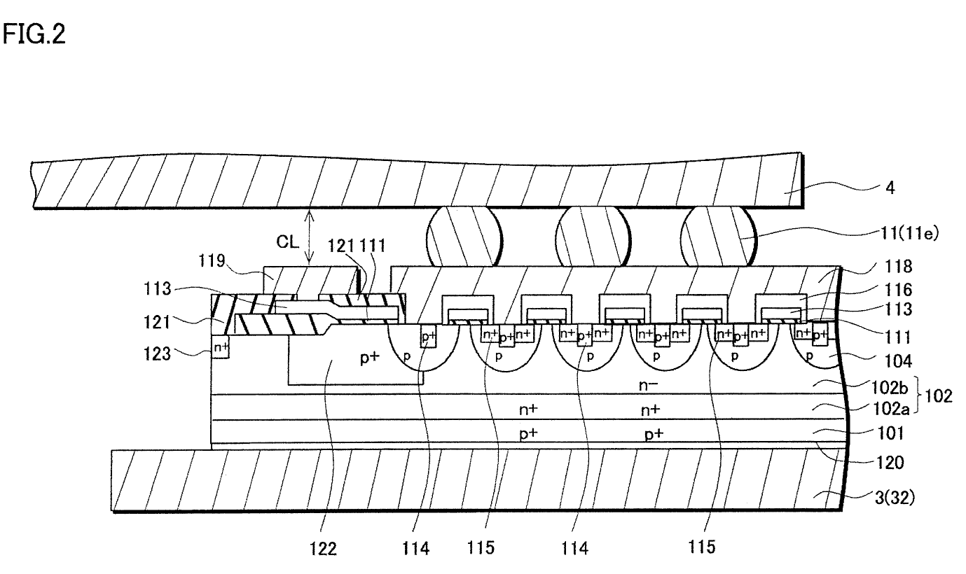

FIG. 2 schematically shows a transistor cell and bump electrodes which are formed in the semiconductor chip of the present embodiment. FIG. 2 is a cross-sectional view taken along the b-b line in FIG. 1A and shows an n channel type IGBT as one example. Note that in the following, the first semiconductor chip 1 will be described but the second semiconductor chip 2 has the same structure.

A collector region is provided on a p+ type (silicon) semiconductor substrate 101 by stacking, for example, an n+type semiconductor layer 102a and n− type semiconductor layer 102b, which serve as a drift region 102. These semiconductor layers may be formed by growing an n+ type epitaxial layer 102a and an n− type epitaxial layer 102b on the p+ type semiconductor layer (substrate) 101. Alternatively, an n+ type semiconductor layer 102a and a p type low resistance layer 101 may be formed by performing impurity diffusion on one main surface side of the n− type semiconductor substrate 102b.

P type base regions 104 are provided on the surface of the n− type semiconductor layer 102b. A gate insulating film (oxide film) 111 is provided on the surfaces of the base regions 104 and a gate electrode 113 are provided on the gate insulating film 111. An interlayer insulating film 116 is provided on the gate electrode 113. The circumference of the gate electrode 113 is covered with the gate insulating film 111 and the interlayer insulating film 116.

An emitter region 115 is provided in each of the base regions 104 and is a high concentration n type impurity region. The emitter region 115 is provided in a portion which is partially below and outside the gate electrode 113. A body region 114, which is a high concentration p type impurity region, is provided on the surface of the base region 104 between the emitter regions 115. The emitter regions 115 and the body regions 114 come in contact with the emitter electrode 118 through contact holes between the interlayer insulating films 116. Thereby, the IGBT transistor cell is configured.

For example, the gate electrode 113 extends, with the insulating film 111 interposed therebetween, on a guard ring region 122 at an end portion of the base region 104 and is further connected to the gate wiring 119 through an opening portion which is provided in the insulating film 121 covering the gate electrode 113. The gate wiring 119 is formed of the same metal layer as the metal layer of the emitter electrode 118 and is connected to the gate pad electrode (which is unillustrated here).

On the emitter electrode 118 and the gate pad electrode, provided are the first bump electrode 11 (the emitter bump electrodes 11e or the gate bump electrode), which are formed of, for example, gold bumps or solder bumps. The first bump electrode 11 is connected to the second frame 4 (the first and second lead portions 411 and 412).

The collector electrode 120 is a lining electrode, made of gold or the like, provided on the back surface of the first semiconductor chip 1 and fixed to the first frame 3 (header portion 32).

As shown in FIG. 2, the emitter electrode 118 and the gate wiring 119 are formed of the same metal layer with similar thicknesses. Accordingly, if the second frame 4 is directly fixed to the emitter electrode 118 without providing the first bump electrode 11 and is led to the outside, it is needed that a predetermined clearance CL is secured by folding the second frame above the gate wiring 119 in order to prevent short-circuit with the gate wiring 119 provided in the circumference of the chip. However, the second frame in the present embodiment is commonly used in the first and second semiconductor chips 1 and 2. For this reason, the configuration in which the second frame is folded in any direction in order to secure the clearance CL is not suitable.

For this reason, the emitter electrode 118 and the gate pad electrode are connected to the second frame 4 by using the first bump electrode 11. Note that diameters of the respective bump electrodes 11 and 21 are, in practice, for example, approximately 25 μm and are much larger than those shown in the figure in relation to the cell. Thereby, the clearance CL above the first and second semiconductor chips 1 and 2 can be sufficiently secured. Thus, the second frame 4 can horizontally be led to the outside of the chip without being folded on the first semiconductor chip 1 and under the second semiconductor chip 2 (a region to an annular region 123 at the chip end). Note that, the lead portion 41 of the second frame 4 (and the lead portion 31 of the first frame 3, if needed) is folded in a desired shape outside of the first and second semiconductor chips 1 and 2 or outside of the resin layer 5 as shown by the alternate long and short dash line in FIG. 1A and FIG. 1B.

As described above, the case where IGBTs with the same chip size and the same pattern are used as the first and second semiconductor chips 1 and 2 has been described. However, the chip sizes and the patterns are not necessarily the same. In addition, the first and second chips 1 and 2 may be discrete semiconductor elements, such as, for example, IGBT and diode, each having different functions.

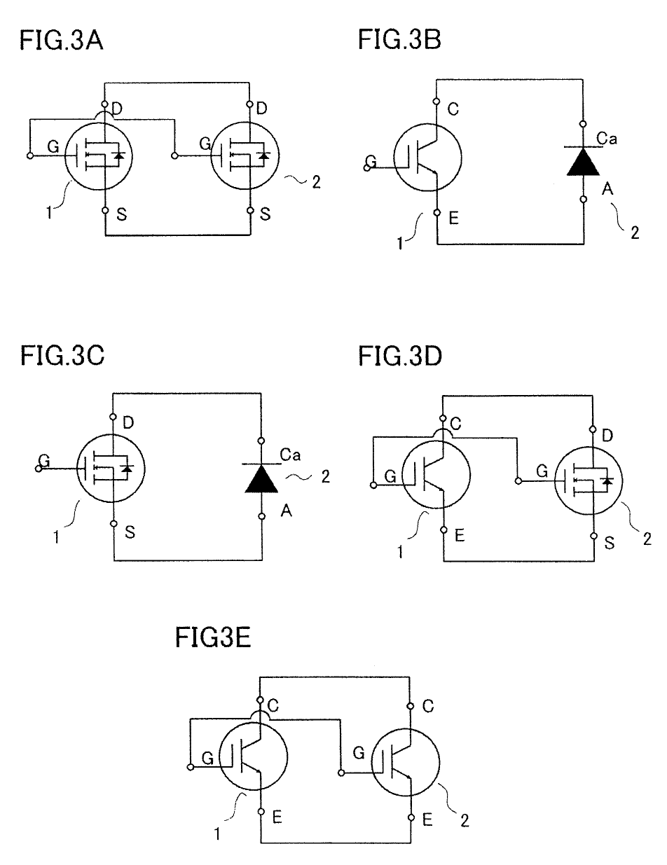

A few examples are described by referring to an equivalent circuit diagram in FIGS. 3A to 3E. Note that the plan view of the first and second semiconductor chips 1 and 2 is similar to FIG. 1A. In addition, in the following example, the plan views of the first and second semiconductor chips 1 and 2 are also similar even if the first and second semiconductor chips 1 and 2 are exchanged.

FIG. 3A shows a case where the first and second semiconductor chips 1 and 2 are both MOSFETs.

FIG. 3B shows a case where the first semiconductor chip 1 is IGBT and the second semiconductor chip 2 is a diode. For example, if the second semiconductor chip 2 is a diode, two terminals are provided and the gate bump electrode 21g shown in FIG. 1A is not provided. Thus, the second semiconductor chip 2 is not connected to the lead portion 412 of the second frame 4. An anode of the diode is connected to the second bump electrode 21 corresponding to the emitter bump electrodes 21e shown in FIG. 1A, and then connected to the lead portion 411 of the second frame 4. In addition, a cathode of the diode is fixed to the header portion 32 of the first frame 3 and then connected to the lead portion 31.

FIG. 3C shows a case where the first semiconductor chip 1 is a MOSFET and the second semiconductor chip 2 is a diode.

FIG. 3D shows a case where the first semiconductor chip 1 is a MOSFET and the second semiconductor chip 2 is IGBT.

In addition, FIG. 3E shows a case, described in FIGS. 1A and 1B, where the first semiconductor chip 1 is IGBT and the second semiconductor chip is also IGBT.

According to the present invention, two semiconductor chips are stacked, and are then fixed to a frame. Thereby, characteristics for the two semiconductor chips can be obtained while a mounting area of a package remains same as the required area for one semiconductor chip of a conventional type. Accordingly, compared with a case in which one semiconductor chip is used, on-resistance is decreased due to an increase in the number of transistor cells. Thereby, a semiconductor device can be driven at a low voltage. In addition, a larger current capacity can be achieved.

Moreover, compared with a case in which two semiconductor chips are mounted next to each other on a single plane (or a chip having a large number of cells and being large in size is used), a mounting area of a package outline can be reduced.

In addition, the semiconductor device has a structure in which surfaces of the two semiconductor chips (for example, emitter electrodes (source electrodes) and gate electrodes) are caused to face to each other. Thereby, complication of manufacturing processes can be avoided. The electrode patterns of the emitter electrode (source electrode) and the gate electrode need to be separated. Accordingly, in a structure where back surfaces of the chips (collector (drain) electrodes) are caused to face to each other (that is, a structure in which the emitter electrode (source electrode) and the gate electrode are arranged outside), manufacturing processes are complicated. In the present embodiment, a stacked structure of two semiconductor chips can be easily obtained.

Furthermore, the semiconductor device according to the present invention has a structure in which one frame (first frame) with two semiconductor chips mounted thereon is folded. Accordingly, a heat releasing property is uniform compared with the case in which, for example, multiple metal plates are bonded to form a single frame. Thus, the structure of the present invention has an advantage of being capable of contributing to a decrease in a resistance value.

In addition, the lead portion (lead pin) of the first frame to serve as a high potential drain terminal (or collector terminal) and the lead portion (lead pin) of the second frame to serve as a low (GND) potential source terminal (or emitter terminal) are caused to face each other. Accordingly, enough distance can be provided between the high potential lead pin and the low potential lead pin. Accordingly, a higher breakdown voltage can be achieved compared with the structure in which the high potential lead pin and the low potential lead pin are led out to the same side of the package.

What is claimed is:

1. A semiconductor device comprising:
a first frame comprising a header portion and a first lead portion extending from the header portion, the header portion comprising a first mounting region and a second mounting region and being bent over so that the first mounting region faces the second mounting region;
a first discrete semiconductor chip comprising a bottom surface attached to the first mounting region and a top surface on which a first bump electrode is formed;
a second discrete semiconductor chip comprising a bottom surface attached to the second mounting region and a top surface on which a second bump electrode is formed; and
a second frame disposed between the first and second mounting regions and connected to the first and second discrete semiconductor chips, the second frame comprising a second lead portion.

2. The semiconductor device of claim 1, wherein the header portion has a shape of a rectangle comprising a short side and a long side and is bent over with respect to a line parallel to the short side, and the first and second lead portions extend, in plan view of the semiconductor device, from the bent header portion in the direction of the short side.

3. The semiconductor device of claim 1, wherein the first discrete semiconductor chip faces the second discrete semiconductor chip having the second frame interposed therebetween, and the first and second bump electrodes are in contact with the second frame.

4. The semiconductor device of claim 1, wherein the second lead portion comprises a first sub-portion and a second sub-portion that are electrically separated, and the first and second discrete semiconductor chips share the first sub-portion and the second sub-portion of the second lead portion as a first and second terminal of the semiconductor device.

5. The semiconductor device of claim 4, wherein the first and second discrete semiconductor chips share the first lead portion as a third terminal of the semiconductor device.
